(19) United States
(12) Patent Application Publication
(10) Pub. No.: US 2006/0214207 A1
(43) Pub. Date: Sep. 28, 2006

(54) Semiconductor device and manufacturing method thereof

(76) Inventors: Toshihide Nabatame, Tsukuba (JP); Masaru Kadoshima, Tsukuba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/389,121

(22) Filed: Mar. 27, 2006

(30) Foreign Application Priority Data
Mar. 28, 2005 (JP) JP2005-90591

(51) Int. Cl. H01L 29/94

(52) U.S. Cl. 257/295

(57) ABSTRACT

Threshold voltage of a CMOS transistor which uses a gate insulator made of a hafnium-based high-k material is optimized. A gate insulator of nMOS and pMOS transistors includes a HfOx film and a HfAlOx film formed thereon. At this time, silicon atoms in a n type polycrystalline silicon film which constitutes a gate electrode and Hf atoms in the HfAlOx film are bonded (Hf—Si bonding) and silicon atoms in the n type polycrystalline silicon film and Al atoms in the HfAlOx film are bonded (Al—O—Si bonding) at the interface between the HfAlOx film and the gate electrode. Consequently, the work function of the n type polycrystalline silicon and the work function of the p type polycrystalline silicon are controlled so as to be symmetrical with respect to a midgap (threshold voltage of MOS transistor=0) by changing the Al concentration in the HfAlOx film.

### CROSS-REFERENCE TO RELATED APPLICATION

The present application claims priority from Japanese Patent Application No. JP 2005-090591 filed on Mar. 28, 2005, the content of which is hereby incorporated by reference into this application.

### TECHNICAL FIELD OF THE INVENTION

The present invention relates to a semiconductor device and a manufacturing technology thereof. More particularly, it relates to a technology effectively applied to a semiconductor device having a CMOS transistor in which a gate insulator made of a hafnium-based high-k material is used.

### BACKGROUND OF THE INVENTION

Conventionally, in a n channel MOS transistor (hereinafter, referred to as a nMOS transistor) and a p channel MOS transistor (hereinafter, referred to as a pMOS transistor) which constitute a CMOS (Complementary Metal Oxide Semiconductor) circuit, a silicon oxide film has been used as a material of a gate insulator, and a polycrystalline silicon film or a polycide film in which a metal silicide film such as a tungsten silicide film or a cobalt silicide film is formed on a polycrystalline silicon film has been used as a material of a gate electrode formed on this gate insulator.

In recent years, however, due to the reduction in size of the MOS transistors which constitute the semiconductor integrated circuit, the thickness of the gate insulator has been rapidly reduced. Therefore, the influence of the depletion which occurs in the gate electrode (polycrystalline silicon film) near the interface of the gate insulator when a voltage is applied to a gate electrode for turning on a MOS transistor has become more and more significant. Therefore, the virtual thickness of the gate insulator is increased. As a result, it becomes difficult to secure the ON current, and the degradation of the operation speed of the transistor becomes remarkable.

Also, when the thickness of the gate insulator is reduced, electrons easily passes through the gate insulator due to the quantum effect called a direct tunneling. As a result, the leakage current is increased. Furthermore, in the pMOS transistor, boron in the gate electrode (polycrystalline silicon film) diffuses into the substrate through the gate insulator, and the impurity concentration in the channel region is increased. Accordingly, the threshold voltage is fluctuated.

For its solution, the replacement of a gate insulator material from the silicon oxide to an insulating material with a dielectric constant higher than that of the silicon oxide (high-k material) has been examined. When the high-k film is used to form the gate insulator, the actual physical thickness can be increased “dielectric constant of high-k film/dielectric constant of silicon oxide film” times even when the equivalent oxide thickness is the same, and accordingly, the leakage current can be reduced. As the high-k material, hafnium oxide (HfOx) and a material obtained by mixing silicon (Si) or aluminum (Al) with the hafnium oxide to increase the crystallization temperature are promising candidates.

Incidentally, the low power consumption design is important in the CMOS circuit, and the reduction of the threshold voltage of the nMOS transistor and the pMOS transistor is required for its achievement. Therefore, when a high-k material such as hafnium oxide is used to form the gate insulator, it is necessary to select a gate electrode material having a work function suitable for the nMOS transistor and the pMOS transistor so as to suppress the increase of the threshold voltage.

For example, Japanese Patent Application Laid-Open Publication No. 2000-252370 (Patent Document 1) discloses a CMOS circuit in which a gate electrode of a nMOS transistor is formed of zirconium or hafnium, and a gate electrode of a pMOS transistor is formed of platinum silicide, iridium silicide, cobalt, nickel, rhodium, palladium, rhenium or gold.

Also, Japanese Patent Application Laid-Open Publication No. 2004-165555 discloses a CMOS circuit in which a gate electrode of a nMOS transistor is formed of any one of titanium, aluminum, tantalum, molybdenum, hafnium and niobium, and a gate electrode of a pMOS transistor is formed of any one of tantalum nitride, ruthenium oxide, iridium, platinum, tungsten nitride and molybdenum nitride.

Also, Japanese Patent Application Laid-Open Publication No. 2004-165346 discloses a CMOS circuit in which a gate electrode of a nMOS transistor is formed of aluminum, and a gate electrode of a pMOS transistor is formed of compound metal obtained by introducing a material having a work function higher than that of aluminum (for example, cobalt, nickel, ruthenium, iridium, platinum and others) into aluminum.

IEEE TRANSACTIONS ON ELECTRON DEVICES, VOL. 51, No. 6, JUNE 2004, pp. 971 to 984 (Non-patent document 1) describes the so-called Fermi-level pinning in which, when the hafnium oxide high-k material is used to form a gate insulator, the work function is effectively varied in comparison with the case where the silicon-based gate insulator is used.

### SUMMARY OF THE INVENTION

As described in the patent document 1, the MOS transistor in which a gate insulator is formed of hafnium oxide has a problem that the low-voltage operation thereof is difficult due to the Fermi-level pinning, in which silicon atoms and hafnium atoms are bonded at the interface with the polycrystalline silicon gate electrode to form a level and thus the threshold voltage is increased.

For its solution, for example, a barrier layer such as a silicon nitride (Si₃N₄) film or an alumina (Al₂O₃) film is provided between a gate electrode and a gate insulator so as to prevent the bonding of silicon atoms and hafnium atoms.

However, since the thickness of at least 1 to 2 nm or more is required in order to produce the sufficient effect of the barrier layer, another problem that the effective dielectric constant of a gate insulator is reduced occurs. Also, since a silicon nitride film has positive fixed potential and an alumina film has negative fixed potential, a steep interface is formed between the barrier layer and the gate insulator to develop a defect, and the problem of the degradation of electrical properties of the MOS transistor occurs. Furthermore, there is also a problem that the hysteresis of the capacitance-voltage (C-V) properties is increased in proportion to the thickness of the barrier layer.

An object of the present invention is to provide a technology capable of optimizing a threshold voltage of a CMOS transistor in which a gate insulator formed of a hafnium-based high-k material is used.

The above and other objects and novel characteristics of the present invention will be apparent from the description of this specification and the accompanying drawings.

The typical ones of the inventions disclosed in this application will be briefly described as follows.

The present invention provides a semiconductor device in which a n channel MOS transistor is formed in a first region on a main surface of a semiconductor substrate made of single crystal silicon and a p channel MOS transistor is formed in a second region on the main surface, wherein each of the n channel MOS transistor and the p channel MOS transistor comprises: a gate insulator including a first dielectric film which contains a first element having a level of silicon bonding on a conduction band side from an energy level located at a midpoint between a conduction band and a valence band of silicon atoms and a second element having a level of silicon bonding on a valence band side therefrom; and a gate electrode including a conductive film which contains silicon, the first dielectric film and the conductive film are stacked on each other, and a ratio of the first element and the second element at an interface with the conductive film and in the vicinity thereof in the first dielectric film is controlled so that a threshold voltage of the n channel MOS transistor and a threshold voltage of the p channel MOS transistor become almost symmetrical with respect to the energy level located at the midpoint.

A manufacturing method of a semiconductor device according to the present invention comprises the steps of: (a) forming a gate insulator including a dielectric film which contains a first element having a level of silicon bonding on a conduction band side from an energy level located at a midpoint between a conduction band and a valence band of silicon atoms and a second element having a level of silicon bonding on a valence band side therefrom, in first and second regions on a main surface of a semiconductor substrate made of single crystal silicon; and (b) forming a gate electrode of a n channel MOS transistor including a conductive film containing silicon in the first region on the gate insulator and a gate electrode of a p channel MOS transistor including the conductive film containing silicon in the second region on the gate insulator, wherein a threshold voltage of the n channel MOS transistor and a threshold voltage of the p channel MOS transistor are controlled by controlling a ratio of the first element and the second element in the dielectric film at the interface with the conductive film and in the vicinity thereof.

The effects obtained by typical aspects of the present invention will be briefly described below.

It is possible to optimize the threshold voltages of a nMOS transistor and a pMOS transistor using a gate insulator made of a hafnium-based high-k material.

### BRIEF DESCRIPTIONS OF THE DRAWINGS

FIG. 1 is a cross-sectional view of the principal part of a semiconductor substrate showing a CMOS circuit according to an embodiment of the present invention;

FIG. 2 is an enlarged cross-sectional view of FIG. 1;

FIG. 3 is a graph showing the effective work functions (Φm. eff) of various gate electrode materials (n type polycrystalline silicon, p type polycrystalline silicon, nickel silicide, and platinum silicide) on a HfAlOx film, plotted while changing the Al concentration in the HfAlOx film;

FIG. 4 is a graph showing the threshold voltages (Vth) of a MOS transistor having a gate electrode composed of a n type polycrystalline silicon film and a MOS transistor having a gate electrode composed of a p type polycrystalline silicon film formed on the HfAlOx film, plotted while changing the Al concentration in the HfAlOx film;

FIG. 5 is a cross-sectional view of the principal part of a semiconductor substrate showing the manufacturing method of a CMOS circuit according to an embodiment of the present invention;

FIG. 6 is a cross-sectional view of the principal part of the semiconductor substrate showing the manufacturing method of a CMOS circuit subsequent to FIG. 5;

FIG. 7 is a cross-sectional view of the principal part of the semiconductor substrate showing the manufacturing method of a CMOS circuit subsequent to FIG. 6;

FIG. 8 is a cross-sectional view of the principal part of the semiconductor substrate showing the manufacturing method of a CMOS circuit subsequent to FIG. 7;

FIG. 9 is a cross-sectional view of the principal part of the semiconductor substrate showing the manufacturing method of a CMOS circuit subsequent to FIG. 8;

FIG. 10 is a cross-sectional view of the principal part of the semiconductor substrate showing the manufacturing method of a CMOS circuit subsequent to FIG. 9; and

FIG. 11 is an enlarged cross-sectional view showing a nMOS transistor which constitutes a CMOS circuit according to another embodiment of the present invention.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

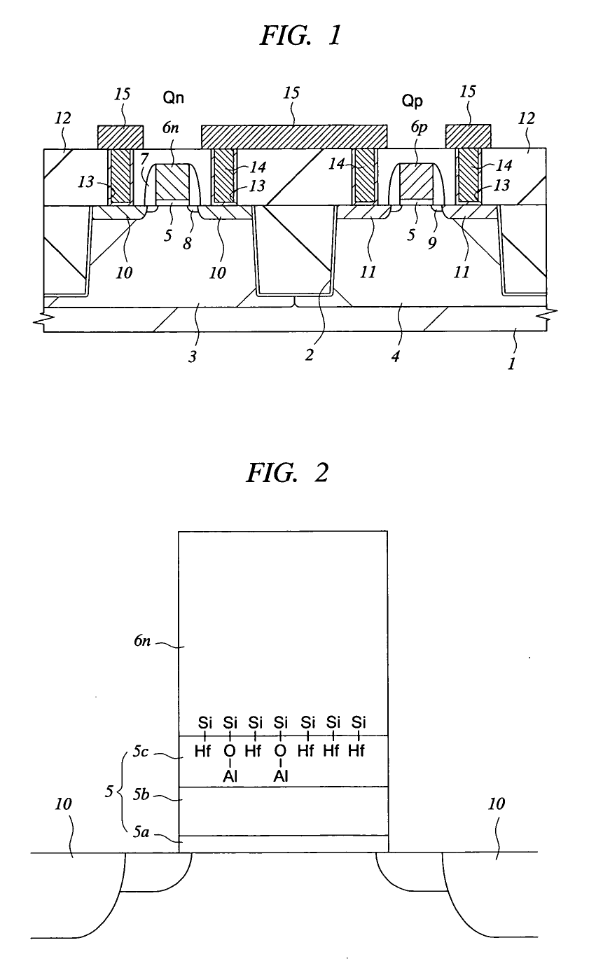

FIG. 1 is a cross-sectional view of the principal part of a semiconductor substrate showing a CMOS circuit (circuit composed of a nMOS transistor Qn and a pMOS transistor Qp) according to the first embodiment.

For example, the nMOS transistor Qn is formed on a p type well 3 in a semiconductor substrate (hereinafter, referred to as a substrate) 1 made of p type single crystal silicon, and the pMOS transistor Qp is formed on a n type well 4 in the substrate 1. The p type well 3 and the n type well 4 are isolated from each other by a device isolation trench 2 formed in the substrate 1.

The nMOS transistor Qn is provided with a gate insulator 5 formed on the p type well 3, a gate electrode 6n made of a n type polycrystalline silicon film formed on the gate insulator 5, and a source and a drain formed near the surface of the p type well 3. The source and drain are formed to have a LDD (Lightly Doped Drain) structure composed of a pair of n⁺ semiconductor regions 10 and n⁻ semiconductor regions 8 formed therebetween. Sidewall spacers 7 composed of a silicon oxide film or a laminated film of a silicon oxide film and a silicon nitride film are formed on the sidewalls of the gate electrode 6n.

The pMOS transistor Qp is provided with a gate insulator 5 formed on the n type well 4, a gate electrode 6p made of a p type polycrystalline silicon film formed on the gate insulator 5, and a source and a drain formed near the surface of the n type well 4. The source and drain are formed to have a LDD structure composed of a pair of p⁺ semiconductor regions 11 and p⁻ semiconductor regions 9 formed therebetween. Sidewall spacers 7 composed of a silicon oxide film or a laminated film of a silicon oxide film and a silicon nitride film are formed on the sidewalls of the gate electrode 6p.

A silicon oxide film 12 is formed on the nMOS transistor Qn and the pMOS transistor Qp, and Al wirings 15 are formed on the silicon oxide film 12. The Al wirings 15 are electrically connected to the nMOS transistor Qn and the pMOS transistor Qp via tungsten plugs 14 in contact holes 13 formed in the silicon oxide film 12.

FIG. 2 is an enlarged cross-sectional view showing the gate insulator 5 and the gate electrode 6n of the nMOS transistor Qn. The gate insulator 5 is composed of a thin silicon oxide film 5a with a thickness of about 0.4 to 1.5 nm formed by annealing the surface of the substrate 1, a HfOx film 5b with a thickness of about 1.5 to 4.0 nm formed on the silicon oxide film 5a, and a thin HfAlOx film 5c with a thickness of about 1.0 nm formed on the HfOx film 5b. Although the silicon oxide film 5a is not always necessary, it is formed in order to stabilize the interface between the gate insulator 5 and the substrate 1.

In the gate insulator 5 with the structure as described above, silicon atoms in the n type polycrystalline silicon film constituting the gate electrode 6n and Hf atoms in the HfAlOx film 5c are bonded (Hf—Si bonding) and silicon atoms in the n type polycrystalline silicon film and Al atoms in the HfAlOx 5c are bonded (Al—O—Si bonding) at the interface between the HfAlOx film 5c and the gate electrode 6n.

Note that it is known that the Hf—Si bonding has a level on a conduction band side from an energy level located at a midpoint between a conduction band and a valence band (=midgap) of silicon atoms. Meanwhile, the Al—O—Si bonding has a level on a valence band side from the midgap of silicon atoms. More specifically, the HfAlOx film 5c contains both the element having a level of the silicon bonding on the conduction band side (Hf) and the element having a level of the silicon bonding on the valence band side (Al).

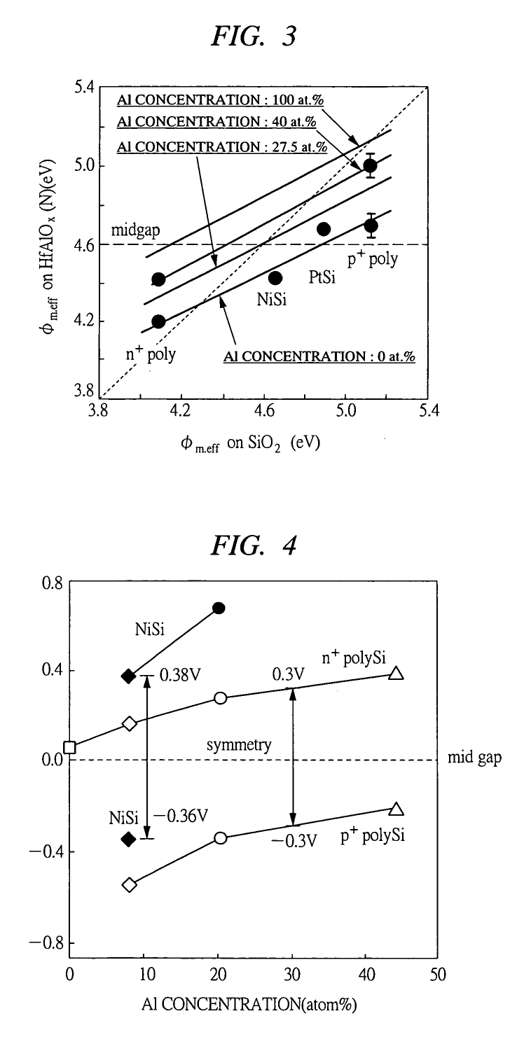

Four solid diagonal lines in FIG. 3 represent the effective work functions (Φm. eff) of various gate electrode materials (n type polycrystalline silicon, p type polycrystalline silicon, nickel silicide, and platinum silicide) on the HfAlOx film, plotted while changing the Al concentration in the HfAlOx film. The dotted diagonal line in FIG. 3 represents the ideal work function of the n type polycrystalline silicon film and the p type polycrystalline silicon film on the silicon oxide film (gate oxide film).

FIG. 3 indicates that the work function of the n type polycrystalline silicon and the work function of the p type polycrystalline silicon can be controlled so as to be symmetrical with respect to the midgap (threshold voltage of MOS transistor=0) by changing the Al concentration in the HfAlOx film. This is because the Hf—Si bonding has the level on the conduction band side from the midgap and the Al—O—Si bonding has the level on the valence band side from the midgap as described above.

FIG. 4 shows the threshold voltages (Vth) of the MOS transistor having a gate electrode composed of a n type polycrystalline silicon film and the MOS transistor having a gate electrode composed of a p type polycrystalline silicon film formed on the HfAlOx film, plotted while changing the Al concentration in the HfAlOx film. As is evident from FIG. 4, when the Al concentration in the HfAlOx film is in the range of 20 to 40 atom %, more preferably, 25 to 35 atom %, the absolute values of the threshold voltages of the two MOS transistors become almost equal to each other. More specifically, by setting the Al concentration in the HfAlOx film 5c constituting a part of the gate insulator 5 within the range of 20 to 40 atom %, more preferably, 25 to 35 atom %, the threshold voltages of the nMOS transistor Qn provided with the gate electrode 6n composed of a n type polycrystalline silicon film and the pMOS transistor Qp provided with the gate electrode 6p composed of a p type polycrystalline silicon film can be optimized.

FIG. 4 also shows the relation between the threshold voltage and the Al concentration in the HfAlOx film in the two types of MOS transistors each having a gate electrode made of nickel silicide. As is evident from FIG. 4, when the Al concentration in the HfAlOx film is about 8 atom %, the absolute values of the threshold voltages of the two types of MOS transistors are almost equal to each other. More specifically, by setting the Al concentration in the HfAlOx film 5c constituting a part of the gate insulator 5 to about 8 atom %, the threshold voltages of the nMOS transistor and the pMOS transistor each having the gate electrode made of nickel silicide can be optimized.

The region where Hf atoms and Al atoms in the HfAlOx film 5c are bonded to silicon atoms in the gate electrode 6n ranges about 0.6 nm from the interface between the HfAlOx film 5c and the gate electrode 6n. Therefore, the thickness of about 1.0 nm is sufficient for the HfAlOx film 5c to leave the un-bonded region. In this case, since Hf in the HfOx film 5b below the HfAlOx film 5c and silicon atoms in the gate electrode 6n are not bonded, the threshold voltage is not varied even when the HfOx film 5b is replaced with a dielectric film other than the HfOx film such as a HfSiOx film or a HfSiOxNy film.

The manufacturing method of a CMOS transistor (nMOS transistor Qn and pMOS transistor Qp) according to this embodiment will be described below.

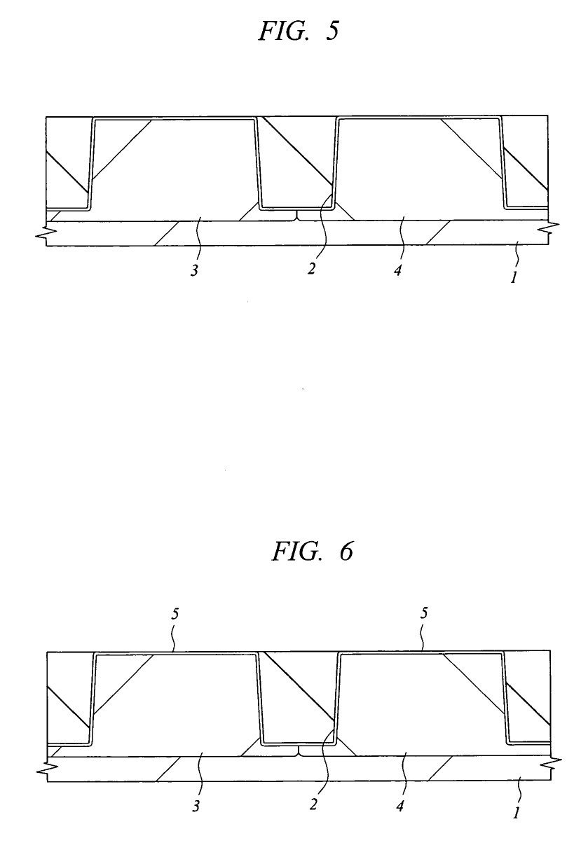

First, as shown in FIG. 5, device isolation trenches 2 are formed in the main surface of the substrate 1 made of p type single crystal silicon through the well-known STI (Shallow Trench Isolation) process. Thereafter, boron is ion-implanted into a nMOS transistor forming region of the substrate 1 (left side in FIG. 5) and phosphorus is ion-implanted into a pMOS transistor forming region of the substrate 1 (right side in FIG. 5). Subsequently, the impurities (boron and phosphorus) are diffused in the substrate 1 by annealing the substrate 1, thereby forming a p type well 3 and a n type well 4 in the main surface of the substrate 1.

Next, after impurities for adjusting the threshold voltage of the MOS transistors are ion-implanted into the respective surfaces of the p type well 3 and the n type well 4, a gate insulator 5 is formed on the respective surfaces of the p type well 3 and the n type well 4 as shown in FIG. 6. The process of forming the gate insulator 5 includes the steps of forming a silicon oxide film 5a by annealing the surface of the substrate 1, and depositing a HfOx film 5b and a HfAlOx film 5c on the silicon oxide film 5a through the ALD process. At this time, the Al concentration in the HfAlOx film 5c is controlled to 20 to 40 atom %, more preferably, 25 to 35 atom %. Note that it is also preferable to introduce nitrogen into the silicon oxide film 5a to form a silicon oxynitride film after forming the silicon oxide film 5a.

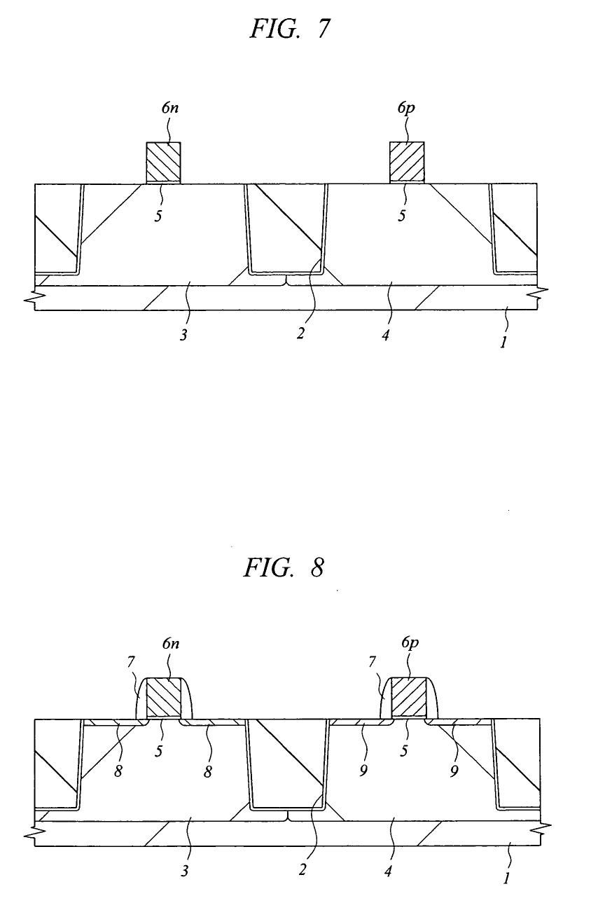

Next, as shown in FIG. 7, a gate electrode 6n composed of a n type polycrystalline silicon film is formed on the gate insulator 5 in the nMOS transistor forming region, and a gate electrode 6p composed of a p type polycrystalline silicon film is formed on the gate insulator 5 in the pMOS transistor forming region. The process of forming the gate electrodes 6n and 6p includes the steps of depositing an undoped polycrystalline silicon film (or undoped amorphous silicon film) on the substrate 1 through the CVD process, ion-implanting phosphorus into the undoped polycrystalline silicon film in the nMOS transistor forming region, ion-implanting boron into the undoped polycrystalline silicon film in the pMOS transistor forming region, and then patterning the polycrystalline silicon film doped with these impurities.

Next, as shown in FIG. 8, phosphorus or arsenic is ion-implanted into the p type well 3 to form n semiconductor regions 8 and boron is ion-implanted into the n type well 4 to form p⁻ semiconductor regions 9. Thereafter, sidewall spacers 7 are formed on the sidewalls of the gate electrodes 6n and 6p. The process of forming the sidewall spacers 7 includes the steps of depositing a silicon nitride film on the substrate 1 through the ALD process, depositing a silicon oxide film on the deposited silicon nitride film through the CVD process, and then anisotropically etching the silicon oxide film.

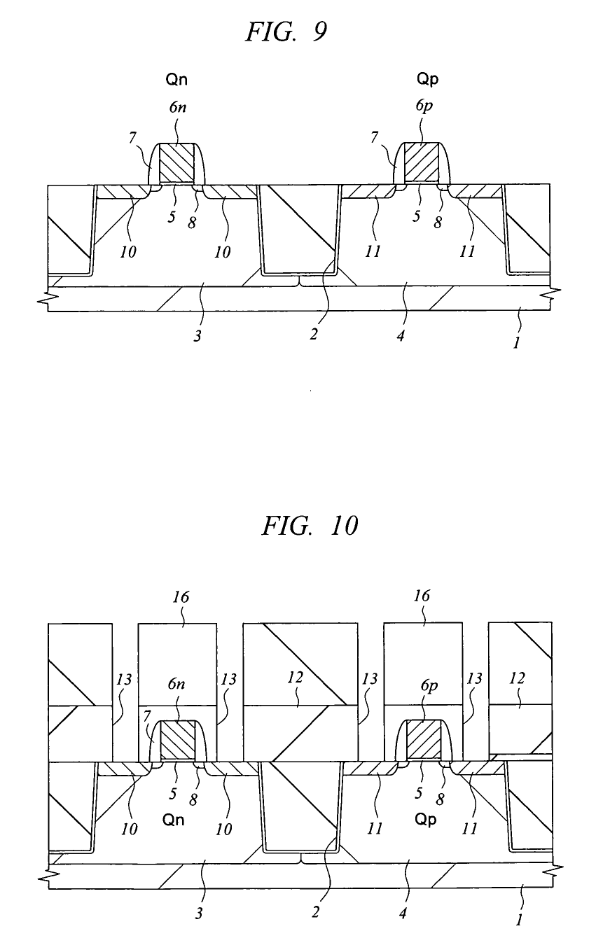

Next, as shown in FIG. 9, after phosphorus or arsenic is ion-implanted into the p type well 3 and boron is ion-implanted into the n type well 4, the substrate 1 is annealed so as to diffuse these impurities. By doing so, n⁺ semiconductor regions (source and drain) 10 are formed in the p type well 3 and p⁺ semiconductor regions (source and drain) 11 are formed in the n type well 4. Through the process as described above, the nMOS transistor Qn and the pMOS transistor Qp are completed.

Next, as shown in FIG. 10, after depositing a silicon oxide film 12 on the substrate 1 through the CVD process, the silicon oxide film 12 is dry-etched with using a photoresist film 16 as a mask, thereby forming contact holes 13 on the n⁺ semiconductor regions (source and drain) 10 and on the p⁺ semiconductor regions (source and drain) 11.

Then, after filling the contact holes 13 with tungsten plugs 14, Al wirings 15 are formed on the silicon oxide film 12. In this manner, the CMOS circuit shown in FIG. 1 is obtained.

### Second Embodiment

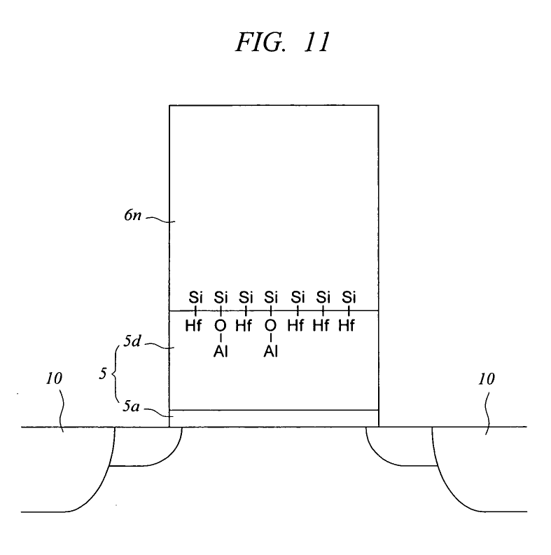

FIG. 11 is an enlarged cross-sectional view of the principal part showing a gate insulator 5 and a gate electrode 6n of a nMOS transistor Qn according to the second embodiment.

The gate insulator 5 of the nMOS transistor Qn according to this embodiment is composed of a thin silicon oxide film 5a with a thickness of about 0.4 to 1.5 nm and a HfAlOx film 5d with a thickness of about 2.5 to 5.0 nm formed on the silicon oxide film 5a. Similar to the first embodiment, the gate electrode 6n is composed of a n type polycrystalline silicon film.

The feature of the HfAlOx film 5d lies in that the Al concentration in the film is highest at the interface with the gate electrode 6n and it gradually decreases toward the substrate 1. The Al concentration in the film at the interface with the gate electrode 6n and in the vicinity thereof is 20 to 40 atom %, more preferably, 25 to 35 atom % similar to the first embodiment. Also, it is desired that the Al concentration in the HfAlOx film 5d at the interface with the silicon oxide film 5a and in the vicinity thereof is 0 atom %. When the HfAlOx film 5d containing Al contacts the silicon oxide film 5a, defects occur in some cases in the interface thereof due to the mismatch in the atomic valence of Al and Si. Though not illustrated, the gate electrode of the pMOS transistor Qp is composed of a p type polycrystalline silicon film similar to the first embodiment, and the gate insulator 5 thereof is composed of the silicon oxide film 5a and the HfAlOx film 5d similar to the nMOS transistor Qn of this embodiment. Also in this HfAlOx film 5d, the Al concentration is highest at the interface with the gate electrode and it gradually decreases toward the substrate 1.

In the gate insulator 5 of the first embodiment, since the HfOx film 5b containing no Al is provided below the HfAlOx film 5c, a steep interface is formed between the HfAlOx film 5c and the HfOx film 5b to develop a defect, and there is the possibility that the electrical properties of the MOS transistors are degraded. However, since such a steep interface is not provided in the gate insulator 5 of the second embodiment, the occurrence of the defect can be prevented.

It is difficult to form the HfAlOx film 5d, in which the Al concentration gradually decreases toward the substrate 1 from the interface with the gate electrode 6n, through the CVD process. However, the HfAlOx film 5d having the Al concentration profile as described above can be formed by depositing HfOx films and Al₂O₃ films through the ALD (Atomic Layer Deposition) process which can deposit films in units of atomic layers, while gradually increasing the ratio of the Al₂O₃ films.

In the foregoing, the invention made by the inventors of the present invention has been concretely described based on the embodiments. However, it is needless to say that the present invention is not limited to the foregoing embodiments and various modifications and alterations can be made within the scope of the present invention.

In the embodiments described above, the threshold voltages of the nMOS transistor and the pMOS transistor are optimized by controlling the Al concentration in the HfAlOx film 5c which contains both the element having a level of silicon bonding on the conduction band side (Hf) and the element having a level of silicon bonding on the valence band side (Al). However, the combination of the element having a level of silicon bonding on the conduction band side and the element having a level of silicon bonding on the valence band side is not limited to Hf and Al. Also, the gate electrode material is not limited to a polycrystalline silicon film, and the present invention can be also applied to the case where a polycide film in which a metal silicide film is formed on a polycrystalline silicon film or a single metal silicide film is used as the gate electrode material.

The present invention can be applied to a semiconductor device in which a n channel MOS transistor and a p channel transistor which use a gate insulator made of a high-k material such as hafnium oxide constitute a CMOS circuit.

What is claimed is:

1. A semiconductor device in which a n channel MOS transistor is formed in a first region on a main surface of a semiconductor substrate made of single crystal silicon and a p channel MOS transistor is formed in a second region on said main surface,
wherein each of said n channel MOS transistor and said p channel MOS transistor comprises: a gate insulator including a first dielectric film which contains a first element having a level of silicon bonding on a conduction band side from an energy level located at a midpoint between a conduction band and a valence band of silicon atoms and a second element having a level of silicon bonding on a valence band side therefrom; and a gate electrode including a conductive film which contains silicon,
said first dielectric film and said conductive film are stacked on each other, and
a ratio of said first element and said second element at an interface with said conductive film and in the vicinity thereof in said first dielectric film is controlled so that a threshold voltage of said n channel MOS transistor and a threshold voltage of said p channel MOS transistor become almost symmetrical with respect to said energy level located at the midpoint.

2. The semiconductor device according to claim 1,
wherein said first element is hafnium.

3. The semiconductor device according to claim 2,
wherein said second element is aluminum.

4. The semiconductor device according to claim 3,
wherein said conductive film of said n channel MOS transistor is a n type polycrystalline silicon film, said conductive film of said p channel MOS transistor is a p type polycrystalline silicon film, said first dielectric film is a HfAlOx film and/or HfAlOx(N) film, and Al concentration in said HfAlOx film and/or HfAlOx(N) film at said interface and in the vicinity thereof is 20 to 40 atom %.

5. The semiconductor device according to claim 1,
wherein said conductive film of said n channel MOS transistor is a n type conductive film containing silicon, and said conductive film of said p channel MOS transistor is a p type conductive film containing silicon.

6. The semiconductor device according to claim 4,
wherein the aluminum concentration in said HfAlOx film and/or HfAlOx(N) film at said interface and in the vicinity thereof is 25 to 35 atom %.

7. The semiconductor device according to claim 4,
wherein the ratio of said first element and said second element in said first dielectric film is gradually changed toward said semiconductor substrate from said interface while keeping the aluminum concentration in said HfAlOx film which contacts said conductive film at 20 to 40 atom %.

8. The semiconductor device according to claim 4,
wherein the aluminum concentration in said HfAlOx film and/or HfAlOx(N) film is gradually decreased toward said semiconductor substrate from said interface.

9. The semiconductor device according to claim 8,
wherein said gate insulator further includes an insulator made of silicon oxide or silicon oxynitride formed so as to contact said semiconductor substrate, and the aluminum concentration in said HfAlOx film and/or HfAlOx(N) film at the interface with said insulator and in the vicinity thereof is 0 atom %.

10. The semiconductor device according to claim 2,
wherein said gate insulator further includes a second dielectric film mainly made of one type of hafnium oxide selected from a group of HfO, Hf—Si—O, and Hf—Si—O—N.

11. A manufacturing method of a semiconductor device comprising the steps of:
(a) forming a gate insulator including a dielectric film which contains a first element having a level of silicon bonding on a conduction band side from an energy level located at a midpoint between a conduction band and a valence band of silicon atoms and a second element having a level of silicon bonding on a valence band side therefrom, in first and second regions on a main surface of a semiconductor substrate made of single crystal silicon; and
(b) forming a gate electrode of a n channel MOS transistor including a conductive film containing silicon in said first region on said gate insulator and a gate electrode of a p channel MOS transistor including said conductive film containing silicon in said second region on said gate insulator,
wherein a threshold voltage of said n channel MOS transistor and a threshold voltage of said p channel MOS transistor are controlled by controlling a ratio of said first element and said second element in said dielectric film at the interface with said conductive film and in the vicinity thereof.

12. The manufacturing method of a semiconductor device according to claim 11,
wherein said first element is hafnium.

13. The manufacturing method of a semiconductor device according to claim 12,
wherein said second element is aluminum.

14. The manufacturing method of a semiconductor device according to claim 13,
wherein said conductive film of said n channel MOS transistor is a n type polycrystalline silicon film, said conductive film of said p channel MOS transistor is a p type polycrystalline silicon film, said dielectric film is a HfAlOx film and/or HfAlOx(N) film, and aluminum concentration in said HfAlOx film and/or HfAlOx(N) film at said interface and in the vicinity thereof is controlled to 20 to 40 atom %.

15. The manufacturing method of a semiconductor device according to claim 14,
wherein the aluminum concentration in said HfAlOx film and/or HfAlOx(N) film at said interface and in the vicinity thereof is controlled to 25 to 35 atom %.

16. The manufacturing method of a semiconductor device according to claim 11,
wherein the ratio of said first element and said second element in said dielectric film is gradually changed toward said semiconductor substrate from said interface by depositing said dielectric film through ALD (Atomic Layer Deposition) process.

17. The manufacturing method of a semiconductor device according to claim 14,
wherein the aluminum concentration in said HfAlOx film and/or HfAlOx(N) film is gradually decreased toward said semiconductor substrate from said interface by depositing said HfAlOx film and/or HfAlOx(N) film through ALD process.
